(19) United States
(12) Patent Application Publication
(10) Pub. No.: US 2001/0028080 A1
(43) Pub. Date: Oct. 11, 2001

(54) Semiconductor device and method of fabricating the same

(76) Inventors: Yoshiaki Himeno, Minato-ku (JP); Hiroaki Tsunoda, Minato-ku (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/817,066

(22) Filed: Mar. 27, 2001

(30) Foreign Application Priority Data
Mar. 28, 2000 (JP) 2000-088704

(51) Int. Cl. H01L 27/108; H01L 29/76; H01L 29/94

(52) U.S. Cl. 257/315; 257/296; 438/257

(57) ABSTRACT

A semiconductor device has a structure in which a gate electrode formed on a semiconductor substrate is buried in an interlevel insulating film so that the upper surface of the gate electrode is exposed, and an insulating film not containing boron and phosphorous is formed on this gate electrode. In this structure, the film thickness of the interlevel insulating film is small. This reduces the aspect ratio of a contact hole and improves the quality of burying of the contact hole. Since no interlevel insulating film which usually contains boron and phosphorous exists on the gate electrode, a shape change of the contact hole caused by annealing can be suppressed. This can improve the reliability of contact.

### CROSS-REFERENCE TO RELATED APPLICATIONS

This application is based upon and claims the benefit of priority from the prior Japanese Patent Application No. 2000-088704, filed Mar. 28, 2000, the entire contents of which are incorporated herein by reference.

### BACKGROUND OF THE INVENTION

The present invention relates to a semiconductor device and a method of fabricating the same and, more particularly, to a nonvolatile semiconductor memory using a stacked gate structure MOS transistor as a memory cell transistor.

With the recent improvements of the semiconductor device fabrication technologies, microfabrication of semiconductor memories is advancing. As the density of semiconductor memories becomes ultra high, technologies for maintaining the reliability of such memories have also become important.

The problems of conventional nonvolatile semiconductor memories will be explained below by taking a NAND flash EEPROM (Electrically Erasable and Programmable Read Only Memory) as an example.

FIG. 1 is a plan view of a memory cell region of the NAND flash EEPROM. As shown in FIG. 1, shallow trench isolations (STI) 110 are formed on a silicon substrate 100 to extend in a direction in which bit lines BL run. Portions between adjacent shallow trench isolations 110 are active areas (AA) 120 for forming elements.

Floating gates (FG) are selectively formed in the active areas 120. Control gates (CG) of memory cell transistors and select gates (SG) of select transistors so run as to cover the floating gates FG and to be perpendicular to the active areas 120. In each active area 120, impurity diffusion layers (not shown) serving as source and drain regions are selectively formed to sandwich the floating gates FG, the control gates CG, and the select gates SG, thereby forming select transistors and memory cell transistors.

A contact plug 130 is formed in the drain region of one select transistor, and the drain is connected to the bit line (BL) via this contact plug 130. The source of the other select transistor is connected to the sources of adjacent select transistors by a local source line (not shown) formed by an impurity diffusion layer formed in the shallow trench isolation 110.

A partial sectional structure of this NAND flash EEPROM will be described below. FIGS. 2A and 2C are sectional views taken along lines 2A-2A and 2C-2C, respectively, in a region 140 of FIG. 1. FIG. 2B is a sectional view of a region corresponding to the line 2A-2A, in a peripheral region not shown in FIG. 1.

As shown in FIGS. 2A to 2C, silicon oxide films 150 and 160 are buried in trenches formed in the major surface of the semiconductor substrate 100, thereby forming the shallow trench isolations 110. A gate insulating film 170 is formed on the active area 120 between adjacent shallow trench isolations 110. On this gate insulating film 170, the floating gates FG made of polysilicon films 180 and 190, a floating gate-control gate insulating film 200, and the control gates CG and the select gates SG made of a polysilicon film 210 and a tungsten silicide film 220 are formed.

An impurity diffusion layer 230 is selectively formed in the semiconductor substrate 100 between the gate electrodes in the above construction, thereby forming a select transistor and a memory cell transistor in a memory cell array region and a transistor in a peripheral region. In the select transistor and the transistor in the peripheral region, the floating gate-control gate insulating film 200 is removed. Consequently, the two gate electrodes above and below this floating gate-control gate insulating film 200 are electrically connected.

In addition, silicon oxide films 240 and 250 are formed on the control gates CG and the select gates SG. A silicon nitride film 260 is so formed as to cover the floating gates FG, the floating gate-control gate insulating film 200, the control gates CG (or the select gates SG), and the silicon oxide films 240 and 250.

Furthermore, a BPSG interlevel insulating film 270 is formed to cover the entire surface. This interlevel insulating film 270 is planarized by CMP to leave a residual film about 100 nm thick behind on the control gates CG (or the select gates SG).

A silicon oxide film 280 is formed on this interlevel insulating film 270. In this silicon oxide film 280, the bit line BL is formed in the memory cell array region by a titanium film 290 and a tungsten film 300, and is connected to the drain of the select transistor by the contact plug 130.

In the peripheral region, a metal interconnecting layer connecting to the transistor in this region is formed by the titanium film 290 and the tungsten film 300. In this manner, the NAND flash EEPROM is fabricated.

The problems posed by the structure of the above conventional nonvolatile semiconductor memory will be explained below with reference to FIGS. 3A, 3B, 4A, and 4B. FIGS. 3A and 3B, or 4A and 4B are sectional views corresponding to FIGS. 2A and 2B, i.e., sectional views taken along the bit line BL direction, of the contact portion between the select transistor of the NAND flash EEPROM and the bit line and the contact portion of the peripheral transistor.

In the conventional structure and fabrication method, the BPSG film 270 serving as an interlevel insulating film remains by a thickness of about 100 nm on the control gates CG (the selector gates SG) owing to limitations on the fabrication technology. However, the film thickness of this BPSG film 270 sometimes increases because the controllability of planarization and film thickness adjustment of the BPSG film 270 is low. Since this increases the depth of contact holes as shown in FIGS. 3A and 3B, a contact plug 130 made of a polysilicon film and the tungsten film 300 cannot be well buried in these contact holes (regions 500). This leads to inferior contact.

Furthermore, the silicon oxide film 280 shrinks when annealing is performed after the contact hole is formed in the peripheral region. This shrinkage causes the BPSG film 270 to reflow. As shown in FIGS. 4A and 4B, this reflow of the BPSG film 270 deforms the shapes of the contact holes (regions 510), leading to contact failures.

### BRIEF SUMMARY OF THE INVENTION

It is an object of the present invention to provide a highly reliable nonvolatile semiconductor memory in which changes in contact hole shape are prevented and contact failures are suppressed by improving the quality of burying, and to provide a method of fabricating the same.

To achieve the above object, a semiconductor device according to the first aspect of the present invention comprises

a semiconductor substrate,

a plurality of impurity diffusion regions, selectively formed on the semiconductor substrate,

a plurality of insulated gate electrodes each formed on the semiconductor substrate between two adjacent ones of the plurality of impurity diffusion regions,

a first insulating film formed on the semiconductor substrate to bury the plurality of gate electrodes so as to expose an upper surface of each gate electrode,

a second insulating film formed on the plurality of gate electrodes and on the first insulating film and not substantially containing boron and phosphorous, and

a conductive contact plug extending through the first and second insulating films and connecting to a predetermined one of the plurality of impurity diffusion regions.

A nonvolatile semiconductor memory according to the second aspect of the present invention comprises

a semiconductor substrate,

a first gate insulating film formed on the semiconductor substrate,

a first gate electrode formed on the first gate insulating film,

a second gate insulating film formed on the first gate electrode,

a second gate electrode formed on the second gate insulating film and at least partly overlapping the first gate electrode,

a first insulating film formed on the second gate electrode,

a second insulating film formed on at least side walls of a stacked gate structure and on the semiconductor substrate, the stacked gate structure being formed by stacking the first gate insulating film, the first gate electrode, the second gate insulating film, the second gate electrode, and the first insulating film,

a third insulating film formed on the semiconductor substrate so as to bury side wall portions of the stacked gate structure, and having an upper surface reaching the first insulating film,

a fourth insulating film formed on the first and third insulating films and not substantially containing boron and phosphorous, and

a conductive member buried in a contact hole reaching the semiconductor substrate through the fourth, third, and second insulating films.

A semiconductor device fabrication method according to the third aspect of the present invention comprises the steps of

forming a plurality of insulated gate electrodes on a semiconductor substrate,

forming a third insulating film on at least the plurality of gate electrodes,

forming a first insulating film on the third insulating film and on the semiconductor substrate so as to bury regions between the plurality of gate electrodes,

planarizing the first insulating film by removal until the third insulating film on the gate electrodes is exposed,

forming a second insulating film not substantially containing boron and phosphorous after the step of planarizing the first insulating film,

forming a contact hole reaching the semiconductor substrate through the second and first insulating films, and burying a conductive member reaching the semiconductor substrate into the contact hole.

A nonvolatile semiconductor memory fabrication method according to the fourth aspect of the present invention comprises the steps of

forming a first gate insulating film on a semiconductor substrate,

forming a first gate electrode on the first gate insulating film,

forming a second gate insulating film on the first gate electrode,

forming, on the second gate insulating film, a second gate electrode at least partly overlapping the first gate electrode,

forming a first insulating film on the second gate electrode,

forming a second insulating film on a stacked gate structure and on the semiconductor substrate, the stacked gate structure being formed by stacking the first gate insulating film, the first gate electrode, the second gate insulating film, the second gate electrode, and the first insulating film,

forming a third insulating film on the semiconductor substrate so as to bury the stacked gate structure,

planarizing the third insulating film by reflow,

removing a surface of the third insulating film until the second insulating film on an upper surface of the stacked gate structure is reached,

forming a fourth insulating film on the third and second insulating films,

forming a contact hole reaching the semiconductor substrate through the fourth, third, and second insulating films, and

burying a conductive member reaching the semiconductor substrate into the contact hole.

The nonvolatile semiconductor memory of the present invention has a structure in which no first insulating film is formed on a gate electrode formed on a semiconductor substrate, and a second insulating film not containing boron and phosphorous is formed on this gate electrode. This structure is equivalent to decreasing the film thickness of the first insulating film, i.e., of an interlevel insulating film. Accordingly, the aspect ratio of a contact hole of a semiconductor device can be reduced, and this can improve the quality of burying of the contact hole. In addition, no first insulating film which usually contains boron and phosphorous exists on the gate electrode. So, a shape change of the contact hole caused by annealing can be suppressed. This can improve the reliability of contact.

In the semiconductor device fabrication method of the present invention, a first insulating film for burying a gate electrode is formed on a semiconductor substrate. After this first insulating film is allowed to reflow, the film is removed to substantially the upper surface of the gate electrode. Removing the first insulating film to substantially the upper surface of the gate electrode is equivalent to decreasing the film thickness of an interlevel insulating film. So, the aspect ratio of a contact hole to be formed later can be reduced. In a contact plug formation step, therefore, the contact hole can be well filled with a conductive member. Also, since the first insulating film does not exist on the gate electrode, a shape change of the contact hole caused by annealing can be suppressed. As a result, the reliability of contact can be improved.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a schematic plan view of a memory cell portion of a conventional NAND flash EEPROM;

FIG. 2A is a sectional view taken along a line 2A-2A in FIG. 1 (a memory cell region);

FIG. 2B is a sectional view taken along a line (not shown) corresponding to the line 2A-2A in FIG. 1, in a memory cell peripheral region;

FIG. 2C is a sectional view taken along a line 2C-2C in FIG. 1 (the memory cell region);

FIGS. 3A and 3B are views for explaining conventional bad contact burying, in which FIG. 3A is a sectional view corresponding to FIG. 2A, which shows a contact portion of a select transistor of the NAND flash EEPROM, and FIG. 3B is a sectional view corresponding to FIG. 2B, which shows a contact portion of a peripheral circuit;

FIGS. 4A and 4B are views for explaining conventional contact bending, in which FIG. 4A is a sectional view corresponding to FIG. 2A, which shows a contact portion of a select transistor of the NAND flash EEPROM, and FIG. 4B is a sectional view corresponding to FIG. 2B, which shows a contact portion of a peripheral circuit;

FIG. 5 is a circuit diagram of the major parts of a NAND flash EEPROM according to an embodiment of the present invention;

FIG. 6 is a plan view of a memory cell portion of the NAND flash EEPROM according to the embodiment of the present invention;

FIG. 7A is a sectional view taken along a line 7A-7A in FIG. 6 (a memory cell region);

FIG. 7B is a sectional view taken along a line (not shown) corresponding to the line 7A-7A in FIG. 6, in a memory cell peripheral region;

FIG. 7C is a sectional view taken along a line 7C-7C in FIG. 6;

FIGS. 8 to 37, each of which includes three figures having a suffix “A”, “B”, or “C”, such as FIGS. 8A, 8B and 8C are sectional views showing the steps in fabricating the NAND flash EEPROM according to the embodiment of the present invention in the order of the steps, in which views having suffixes “A”, “B”, and “C” are sectional views corresponding to FIGS. 7A, 7B, and 7C, respectively; and

FIG. 38 is a view for explaining an example in which the present invention is applied to a NOR flash EEPROM, which is a sectional view taken along the bit line direction of the NOR flash EEPROM.

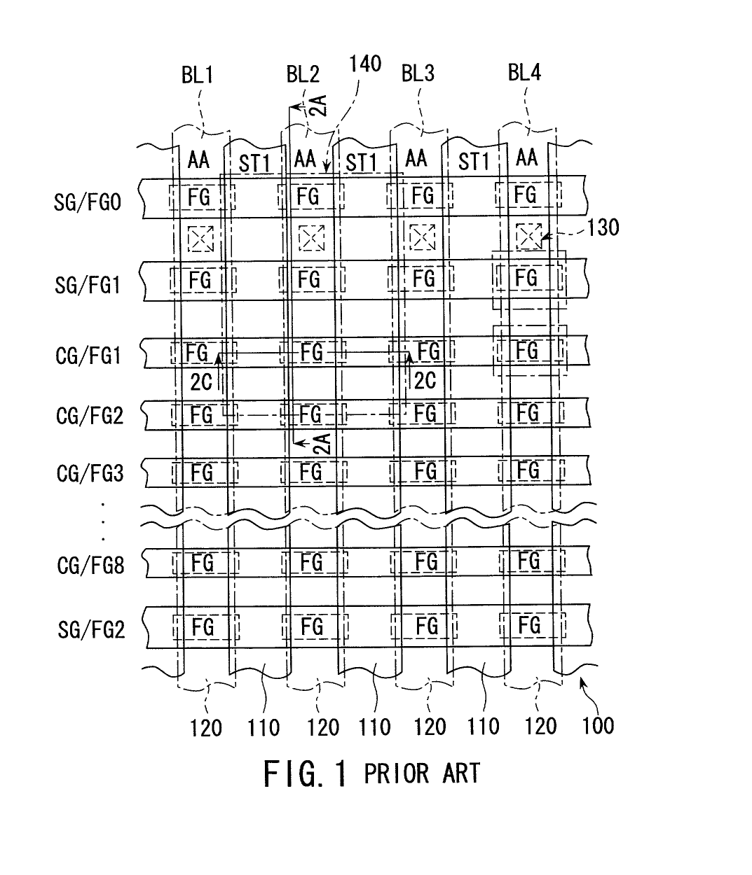

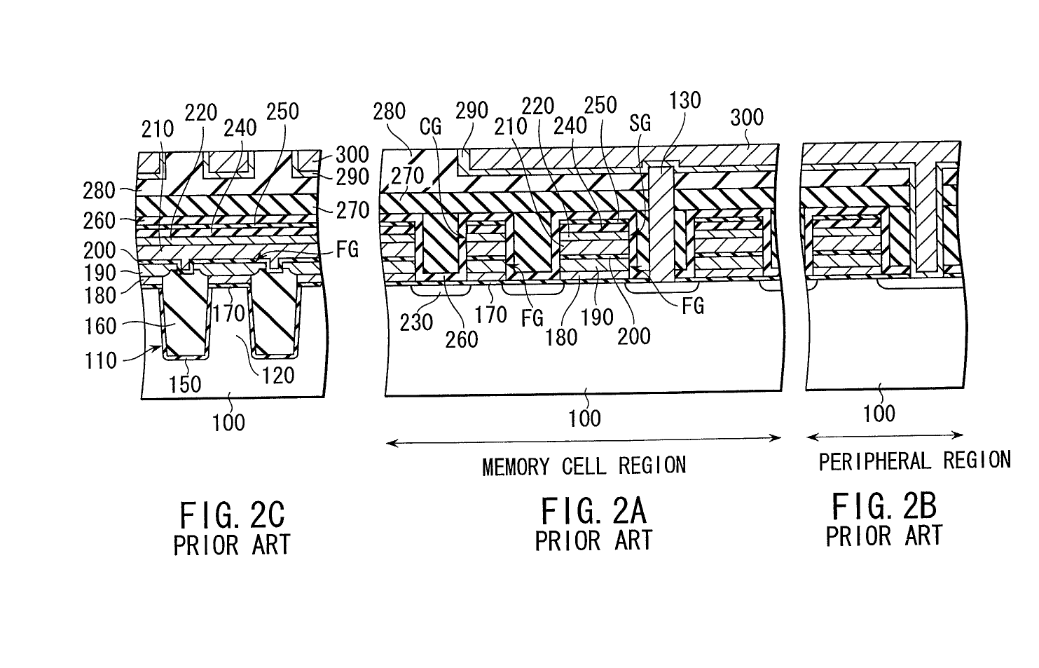

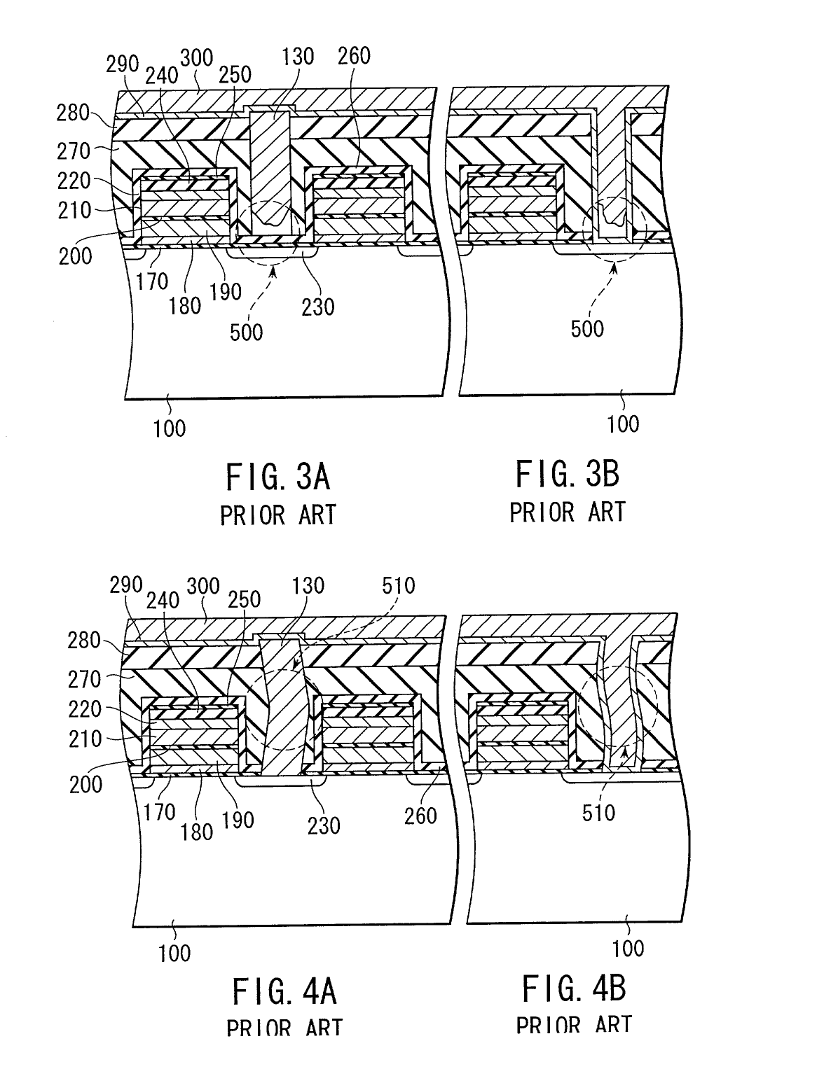

### DETAILED DESCRIPTION OF THE INVENTION

An embodiment of the present invention will be described below with reference to the accompanying drawings. In this description, the same reference numerals denote the same parts in all views. In this embodiment, a method of fabricating a semiconductor memory will be explained by taking a NAND flash EEPROM as an example.

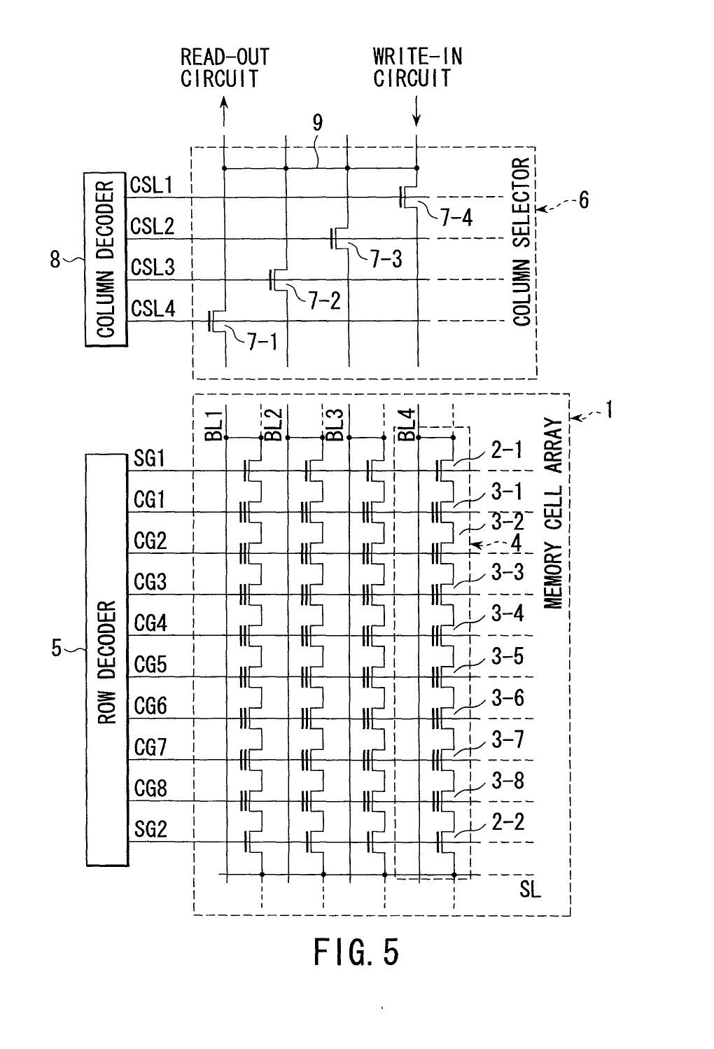

FIG. 5 is a circuit diagram showing a memory cell array and its partial peripheral circuit (column selector) of the NAND flash EEPRPOM according to this embodiment. As shown in FIG. 5, this memory cell array 1 of the NAND flash EEPROM includes a plurality of NAND cells 4 each composed of, e.g., eight memory cell transistors 3-1 to 3-8 connected in series between two select transistors 2-1 and 2-2.

The control gates of the memory cell transistors 3-1 to 3-8 in each NAND cell 4 are connected to control gate lines CG1 to CG8. The select gates of the select transistors are connected to select gate lines SG1 and SG2. These select gate lines SG1 and SG2 and control gate lines CG1 to CG8 are connected to a row decoder 5.

This row decoder 5 selectively drives the control gate lines CG1 to CG8 and the select gate lines SG1 and SG2. The drain of the select transistor 2-1 is connected to one of bit lines BLi (i=1, 2, . . . ) These bit lines BLi are connected to a column selector 6.

The column selector 6 has a plurality of transistors 7-1, 7-2, . . . . One end of the current path of each of these transistors 7-1, 7-2, . . . , is connected to a corresponding one of the bit lines BL1, BL2, . . . . The gates of these transistors are connected to column-select lines CSL1 to CSL4. These column-select lines CSL1 to CSL4 are connected to a column decoder 8.

This column decoder 8 selectively drives the column-select lines CSL1 to CSL4. When the transistors 7-1 to 7-4 connected to these column-select lines CSL1 to CSL4 are selectively driven, one of the bit lines BL1 to BL4 is connected to a read/write node 9. This read/write node 9 is connected to a read-out circuit and a write-in circuit (neither is shown).

The source of the select transistor 2-2 in the NAND cell 4 is connected to a common local source line SL and connected to a source decoder via a global source line (not shown).

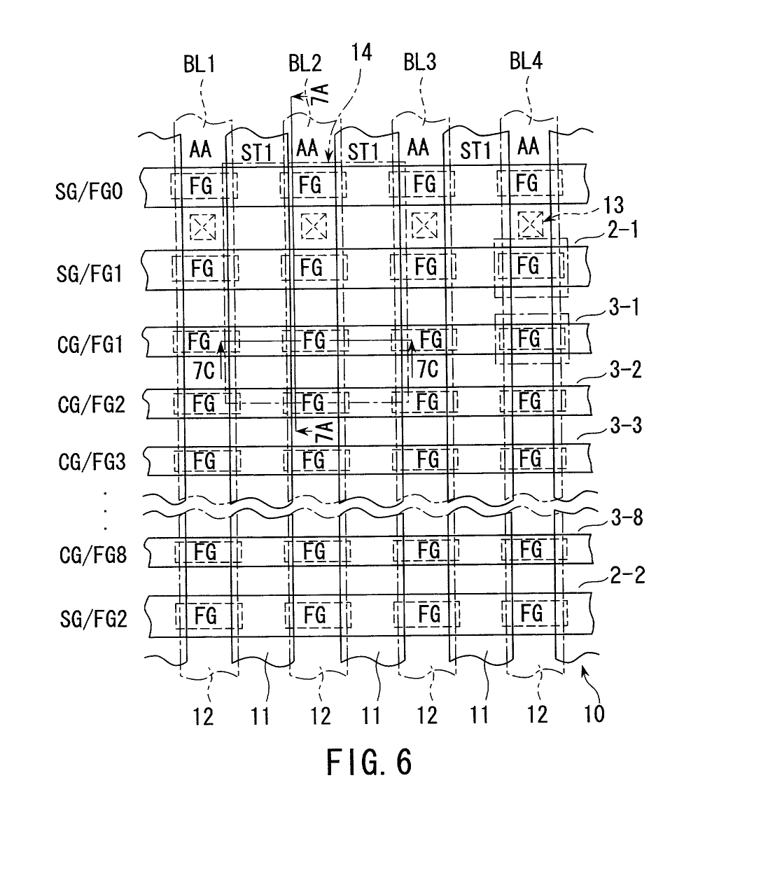

FIG. 6 is a plan view showing a partial pattern of a memory cell array region in the above NAND flash EEPROM. As shown in FIG. 6, shallow trench isolations (STI) 11 are formed on a silicon substrate 10 in a direction in which the bit lines BL run. Portions between these shallow trench isolations 11 are active areas (AA) 12 for forming elements.

Floating gates FG are selectively formed in the active areas 12. Control gates CG and select gates SG so run as to cover these floating gates FG and to be perpendicular to the active areas 12. In the silicon substrate 10 in each active area 12, impurity diffusion layers (not shown) serving as source and drain regions are formed to sandwich the floating gates FG, the control gates CG, and the select gates SG, thereby forming the select transistors 2-1 and 2-2 and the memory cell transistors 3-1 to 3-8.

The drain region of the select transistor 2-1 is connected to the bit line BL via a contact plug 13. The source of the select transistor 2-2 is connected to the source of an adjacent select transistor by the local source line SL formed by an impurity diffusion layer formed in the shallow trench isolation 11.

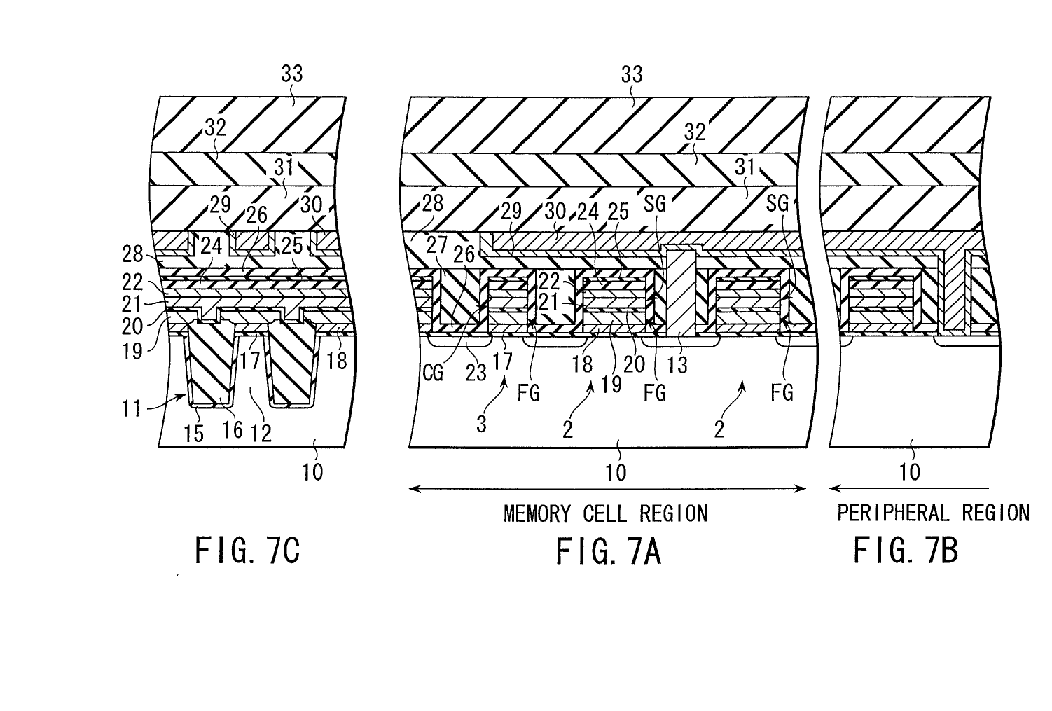

A partial sectional structure of the above NAND flash EEPROM will be described below. FIG. 7A is a sectional view taken along a line 7A-7A in FIG. 6. FIG. 7C is a sectional view taken along a line 7C-7C. FIG. 7B is a sectional view of a region (not shown) corresponding to the line 7A-7A in FIG. 6, in a peripheral region. An example of the peripheral region is a column selector.

As shown in FIGS. 7A to 7C, silicon oxide films 15 and 16 are buried in trenches formed in the major surface of the silicon substrate 10, thereby forming the shallow trench isolations 11. A gate insulating film 17 (first gate insulating film) is formed on the active area 12 between these shallow trench isolations 11. On this gate insulating film 17, the floating gates FG (first gate electrodes) made of polysilicon films 18 and 19, a floating gate-control gate insulating film 20 (second gate insulating film) made of a multilayered ONO (Oxide-Nitride-Oxide) film including silicon oxide and silicon nitride films, and the control gates CG or the select gates SG (second gate electrodes) made of a polysilicon film 21 and a tungsten silicide film 22 are formed.

In the semiconductor substrate 10 between the gate electrodes in the above structure, impurity diffusion layers 23 serving as a source and drain are selectively formed. In this manner, the select transistors 2-1 and 2-2 and the memory cell transistors 3-1 to 3-8 in the memory cell region and the transistors in the peripheral region are formed.

In the select transistor and the transistor in the peripheral region, at least a portion of the floating gate-control gate insulating film 20 is removed. In this way, the two gates above and below the floating gate-control gate insulating film 20 are electrically connected in a region (not shown).

Silicon oxide films 24 and 25 are formed on the control gates CG (selector gates SG). A silicon nitride film 26 (second insulating film) is formed on the entire surface so as to cover the floating gates FG, the floating gate-control gate insulating film 20, the control gates CG (select gates SG), and the silicon oxide films 24 and 25.

Also, an interlevel insulating film 27 (third insulating film) is so formed as to bury portions between the adjacent gate electrodes. A silicon oxide film 28 (fourth insulating film) is formed on this interlevel insulating film 27 and the silicon nitride film 26.

In the silicon oxide film 28, the bit line BL made of a titanium film 29 and a tungsten film 30 is formed in the memory cell array region, and a metal interconnection connecting to the transistors is formed in the peripheral region. The contact plug 13 connecting to the bit line BL is so formed as to connect to the drain region of the select transistor.

A second interlevel insulating film 31 covers the entire surface of the above structure. A passivation film 32 and a coating material 33 are formed on this second interlevel insulating film 31, thereby forming the NAND flash EEPROM.

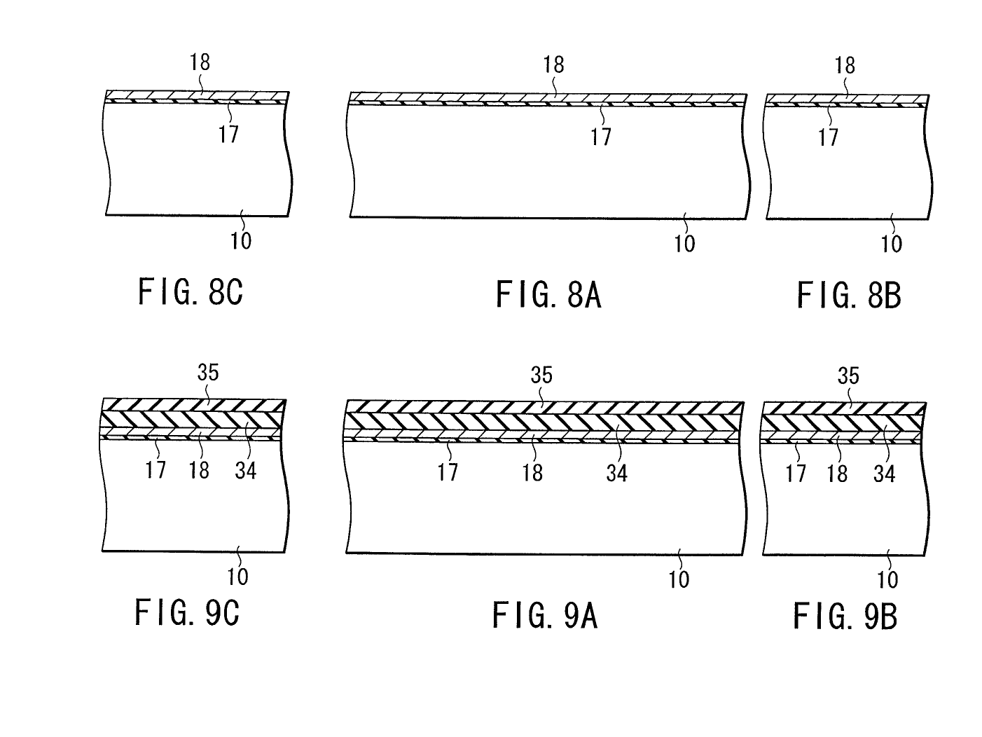

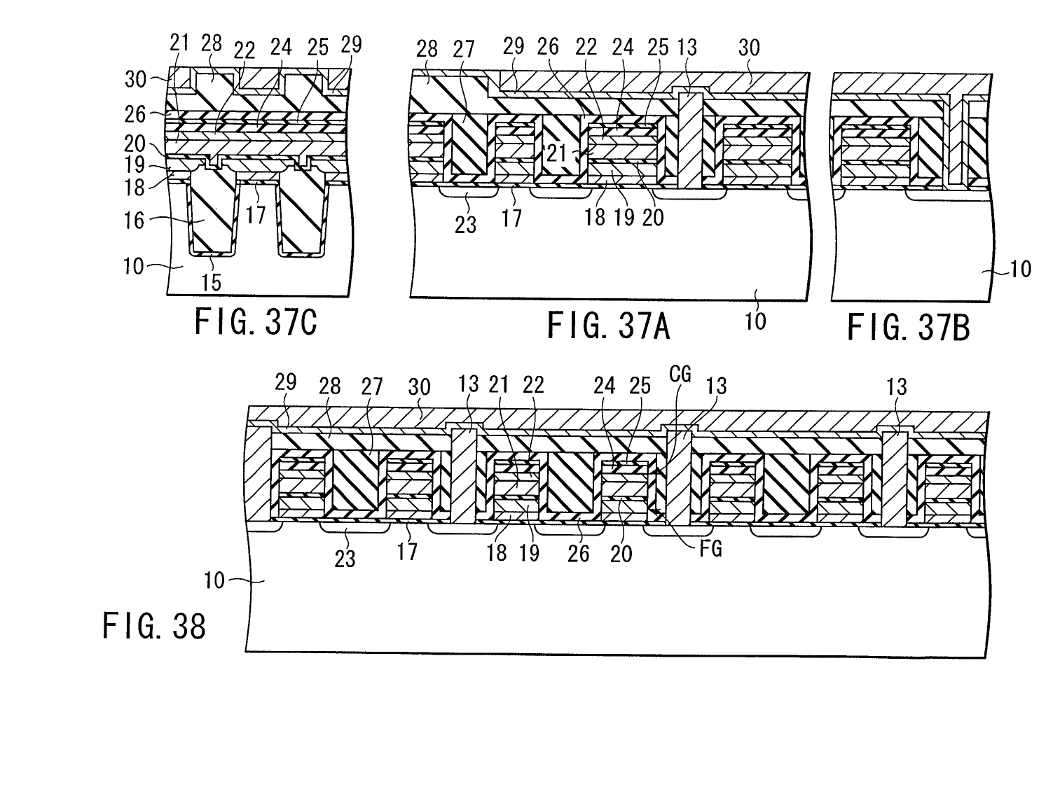

A method of fabricating the NAND flash EEPROM with the above construction will be described below with reference to FIGS. 8A to 8C and 37A to 37C. These views are sectional views showing the fabrication steps of the NAND flash EEPROM in the order of the steps. Views having a suffix A correspond to FIG. 7A, and they are sectional views taken along the bit line direction. Views having a suffix C correspond to FIG. 7C, and they are sectional views taken along the word line direction. Views having a suffix B correspond to FIG. 7B, and they are sectional views taken along the bit line direction in the peripheral region.

As shown in FIGS. 8A to 8C, an 8-nm thick silicon oxide film serving as a gate insulating film 17 is formed on a silicon substrate 10 by thermal oxidation or the like. On this gate insulating film 17, a 60-nm thick polysilicon film 18 is formed by low pressure CVD (Chemical Vapor Deposition) or the like. Although the gate insulating film 17 can remain as a silicon oxide film, it can also be turned into an oxynitride film by nitriding and oxidation using NH₃ gas or the like.

Subsequently, as shown in FIGS. 9A to 9C, a 70-nm thick silicon nitride film 34 and a 230-nm thick silicon oxide film 35 are formed on the polysilicon film 18 by low pressure CVD or the like. Pyrogenic oxidation is performed at 850° C. for 30 min.

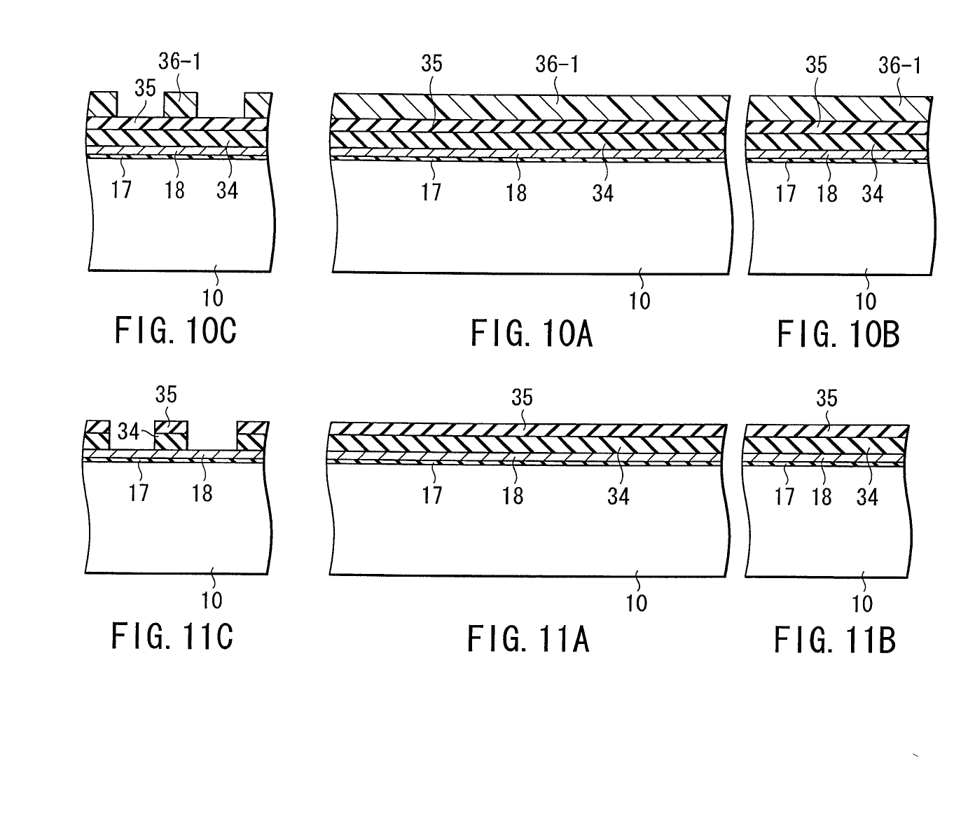

The entire surface is coated with a photoresist 36-1, and this photoresist 36-1 is patterned as shown in FIGS. 10A to 10C by photolithography. This photoresist 36-1 is used as a mask to perform anisotropic etching such as RIE (Reactive Ion Etching), thereby processing the silicon oxide film 35 and the silicon nitride film 34. The photoresist 36-1 is then removed by processing using O₂-plasma and a solution mixture of sulfuric acid and hydrogen peroxide (FIGS. 11A to 11C).

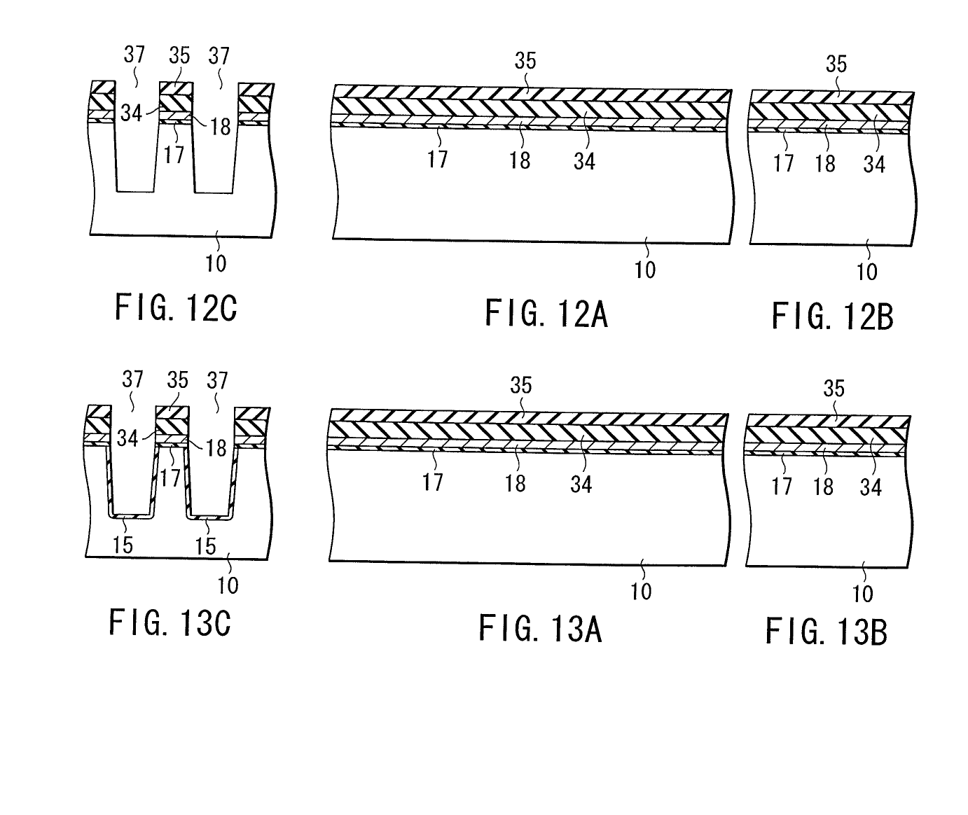

As shown in FIGS. 12A to 12C, the polysilicon film 18, the silicon oxide film 17, and the silicon substrate 10 are sequentially etched by RIE or the like using the silicon oxide film 35 and the silicon nitride film 34 as masks, thereby forming trenches 37 for forming shallow trench isolations.

Annealing is then performed in an oxidizing ambient at 1,000° C. Consequently, as shown in FIGS. 13A to 13C, a 6-nm thick silicon oxide film 15 is formed on the surfaces of the silicon substrate 10 exposed to the surfaces of the trenches 37. This silicon oxide film 15 rounds the corners of the trenches 37 to thereby prevent concentration of stress and the like to these corners.

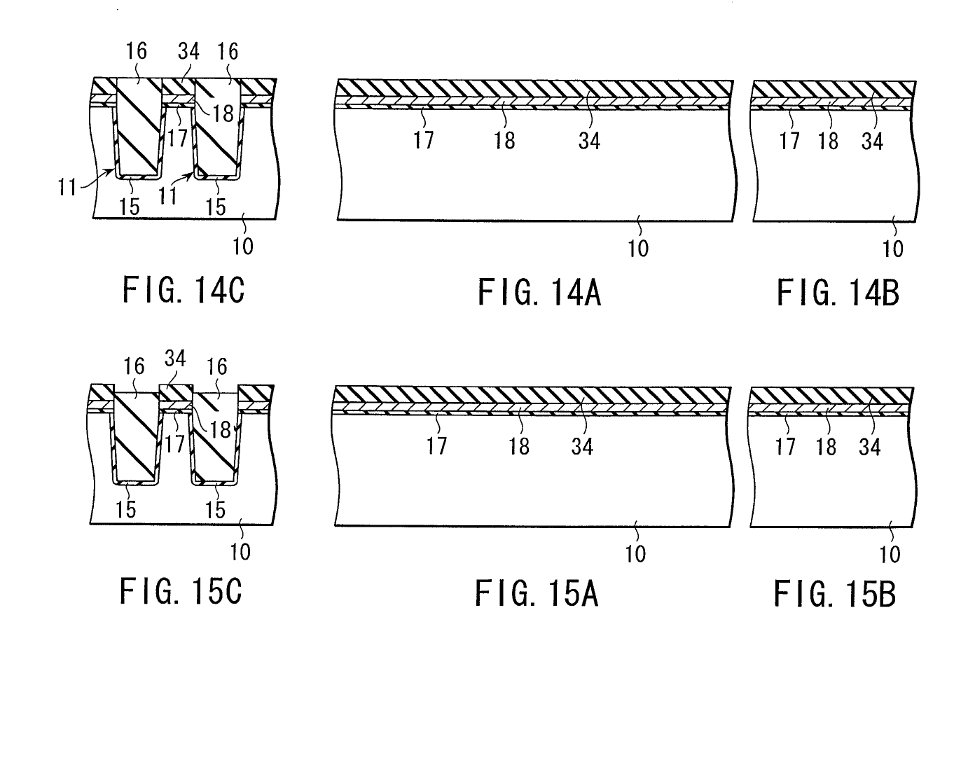

In addition, a 430-nm thick silicon oxide film 16 is formed on the entire surface by an HDP (High Density Plasma) method or the like. As a result, the trenches 37 are filled with this silicon oxide film 16. Subsequently, the silicon oxide films 16 and 35 are planarized by CMP using the silicon nitride film 34 as a stopper, thereby completing shallow trench isolations 11 as shown in FIGS. 14A to 14C.

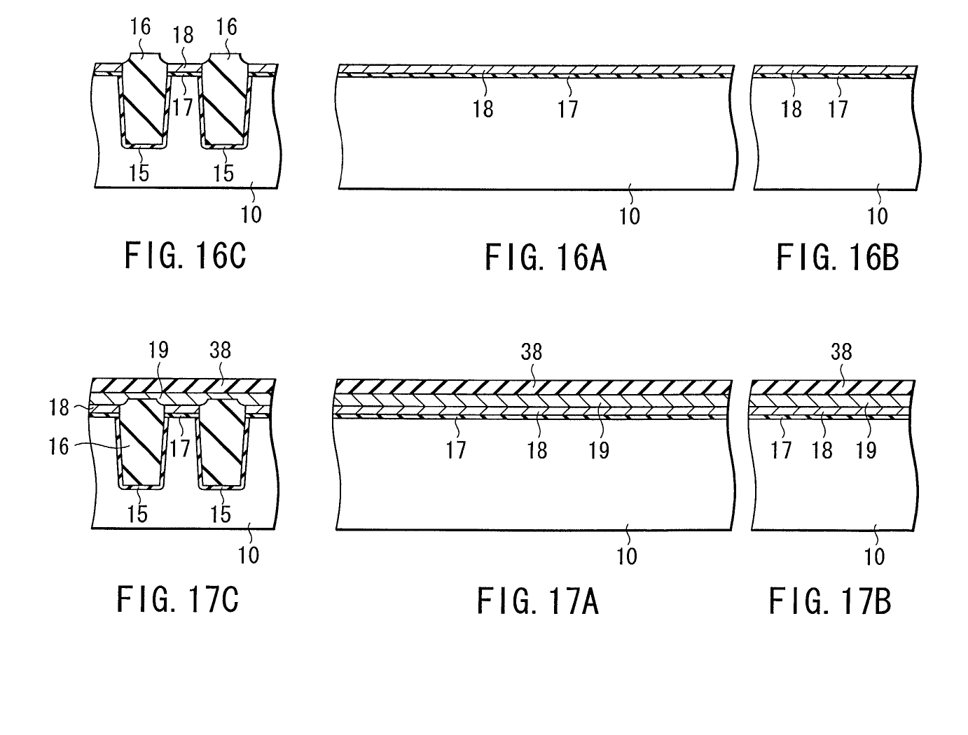

As shown in FIGS. 15A to 15C, the silicon oxide film 16 is etched by 20 nm by an HF solution. Then, as shown in FIGS. 16A to 16C, phosphoric acid processing is performed at 150° C. for 40 min to selectively remove the silicon nitride film 34.

After that, as shown in FIGS. 17A to 17C, a 100-nm thick polysilicon film 19 and a 230-nm thick silicon oxide film 38 are formed in this order by low pressure CVD.

As shown in FIGS. 18A to 18C, the entire surface is coated with a photoresist 36-2, and this photoresist 36-2 is patterned by photolithography. The silicon oxide film 38 is processed by RIE or the like using this photoresist 36-2 as a mask. The resist 36-2 is then removed by processing using O₂-plasma and a solution mixture of sulfuric acid and hydrogen peroxide.

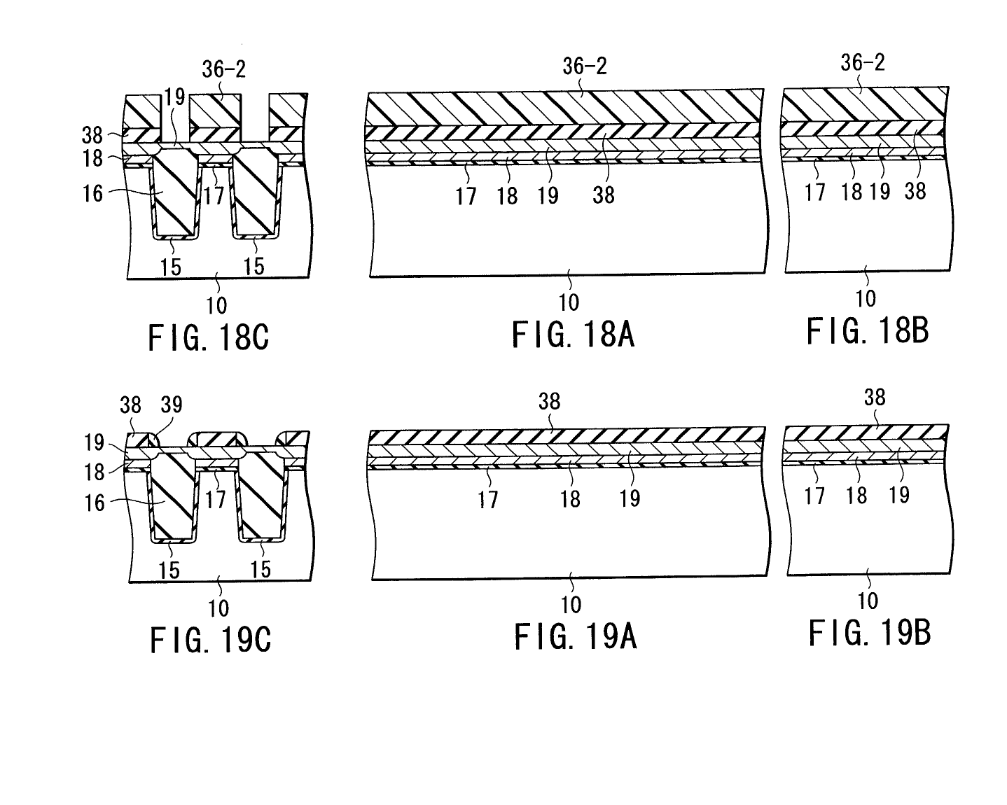

A 70-nm thick silicon oxide film 39 is formed on the entire surface by low pressure CVD or the like. After that, as shown in FIGS. 19A to 19C, this silicon oxide film 39 is etched by whole-surface etch back so as to remain only on the side walls of the silicon oxide film 38.

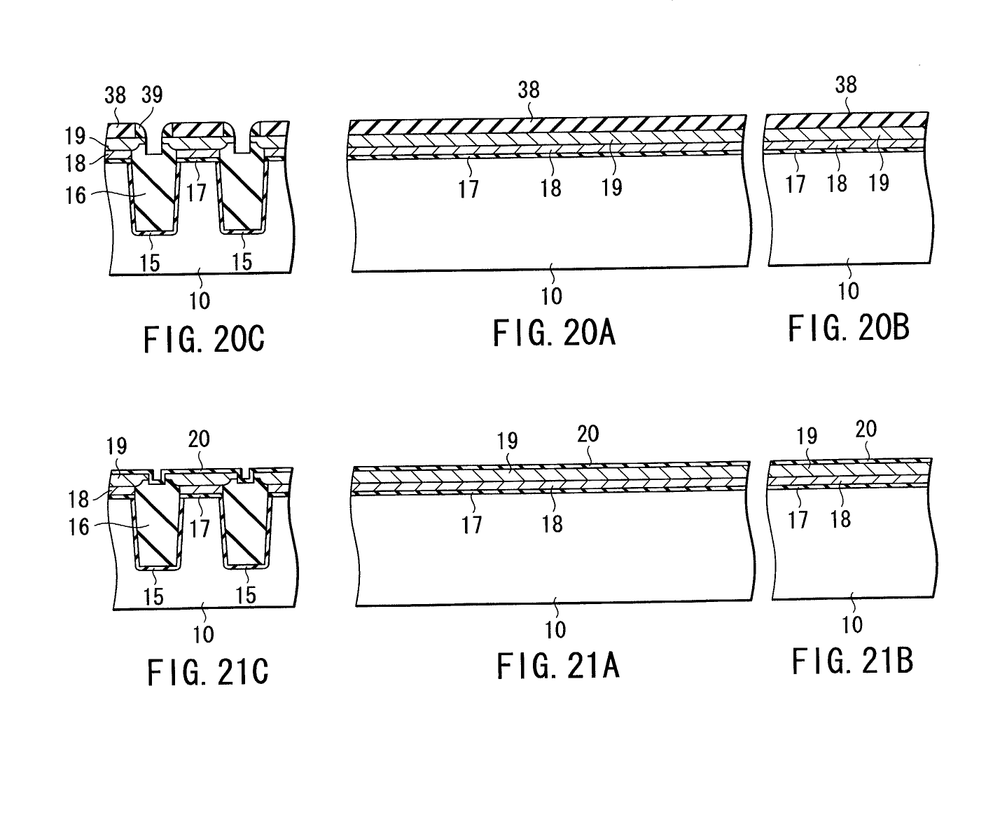

As shown in FIGS. 20A to 20C, portions of the polysilicon film 19 and the silicon oxide film 16 are removed by RIE using the silicon oxide films 38 and 39 as masks. After that, the silicon oxide films 38 and 39 as mask materials are removed by using O₂-plasma and a solution mixture of sulfuric acid and hydrogen peroxide, thereby completing a floating gate FG made of the polysilicon films 18 and 19.

As shown in FIGS. 21A to 21C, a 17-nm thick floating gate-control gate insulating film 20 is formed on the entire surface by low pressure CVD. For example, this floating gate-control gate insulating film 20 is a three-layered ONO film having a silicon oxide film (SiO₂: 5 nm), silicon nitride film (SiN: 7 nm), and silicon oxide film (SiO₂: 5 nm). Note that the floating gate-control gate insulating film 20 can also be a simple silicon oxide film or a two-layered ON or NO film composed of a silicon oxide film and silicon nitride film.

This floating gate-control gate insulating film 20 is removed from partial regions (not shown) of prospective regions of a select transistor and a transistor in a peripheral region. It is of course also possible to remove the floating gate-control gate insulating film 20 from the entire prospective regions.

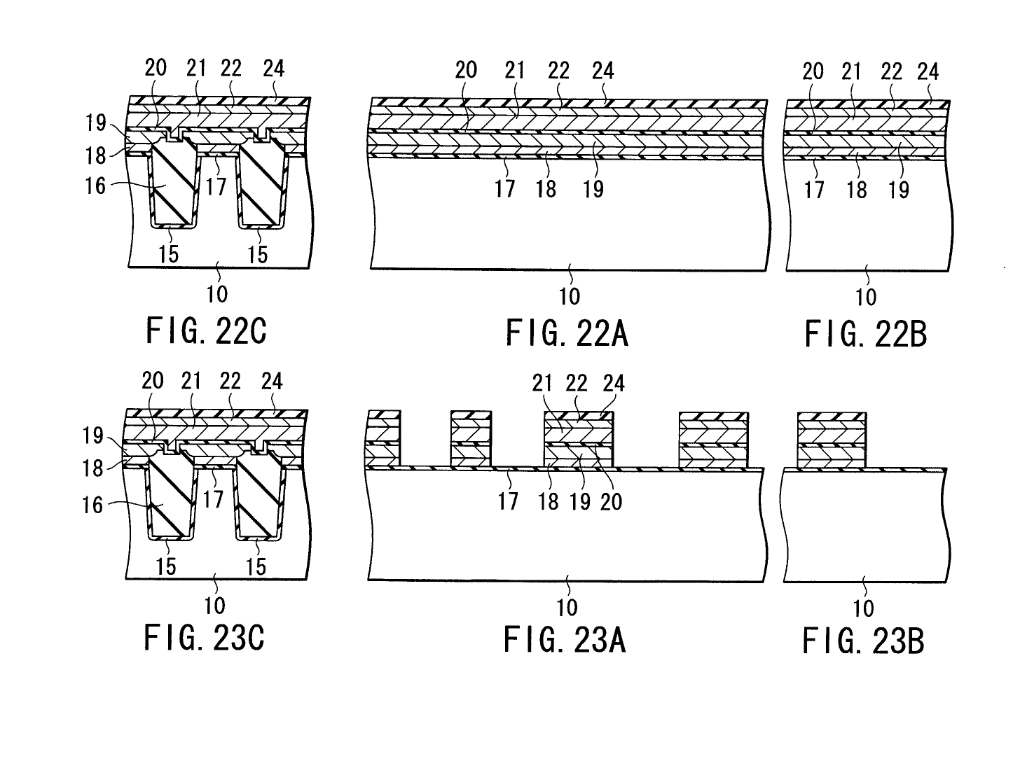

Subsequently, as shown in FIGS. 22A to 22C, an 8-nm thick polysilicon film 21 and a 50-nm thick tungsten silicide film 22 are formed on the floating gate-control gate insulating film 20 by low pressure CVD and PVD (Physical Vapor Deposition), respectively. Furthermore, a 230-nm thick silicon oxide film 24 is formed on the tungsten silicide film 22 by low pressure CVD.

The entire surface is coated with a photoresist (not shown), and this photoresist is patterned into the patterns of a control gate CG of a memory cell transistor and a select gate SG of a select transistor by photolithography. After the silicon oxide film 24 is patterned by RIE using this photoresist as a mask, the photoresist is removed.

RIE using the silicon oxide film 24 patterned in the above step as a mask is then performed to etch the tungsten silicide film 22, the polysilicon film 21, the floating gate-control gate insulating film 20, and the polysilicon films 19 and 18, thereby completing two-layered gates as shown in FIGS. 23A to 23C.

More specifically, the gate electrodes of a memory cell transistor and select transistor are formed by a two-layered structure including the floating gate FG made of the polysilicon films 18 and 19 and the control gate CG (select gate SG) made of the polysilicon film 21 and the tungsten silicide film 22. As described previously, however, the floating gate FG and the select gate SG are electrically connected in a region (not shown) of the select transistor.

Annealing is first performed in a nitrogen ambient at 800° C. and then in an oxidizing ambient at 1,000° C., forming a 10-nm thick silicon oxide film 25 on the silicon oxide film 24. Note that these films 24 and 25 can also be silicon nitride films, instead of silicon oxide films.

After that, an impurity is doped into prospective regions of a source and drain by ion implantation, thereby selectively forming impurity diffusion layers 23. Annealing is performed at 1,050° C. for 30 sec to activate the doped impurity.

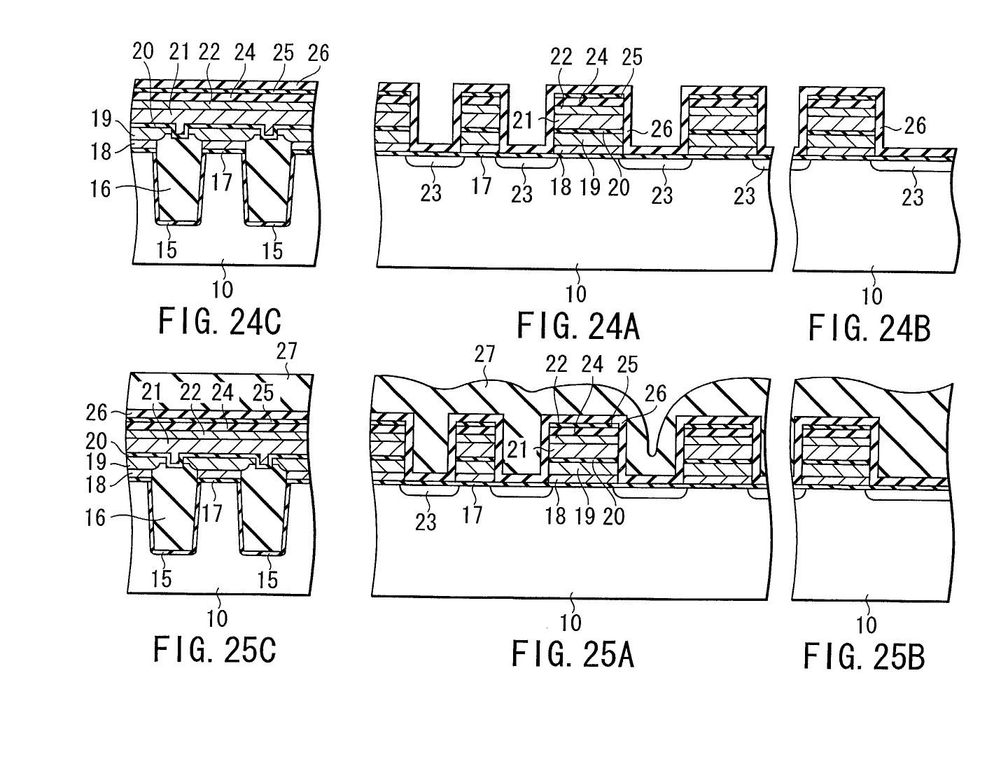

Subsequently, a 40-nm thick silicon nitride film 26 is formed on the entire surface by low pressure CVD. By the steps described so far, a structure shown in FIGS. 24A to 24C is formed, and a memory cell array region and a MOS transistor in a peripheral region of a NAND flash EEPROM are completed.

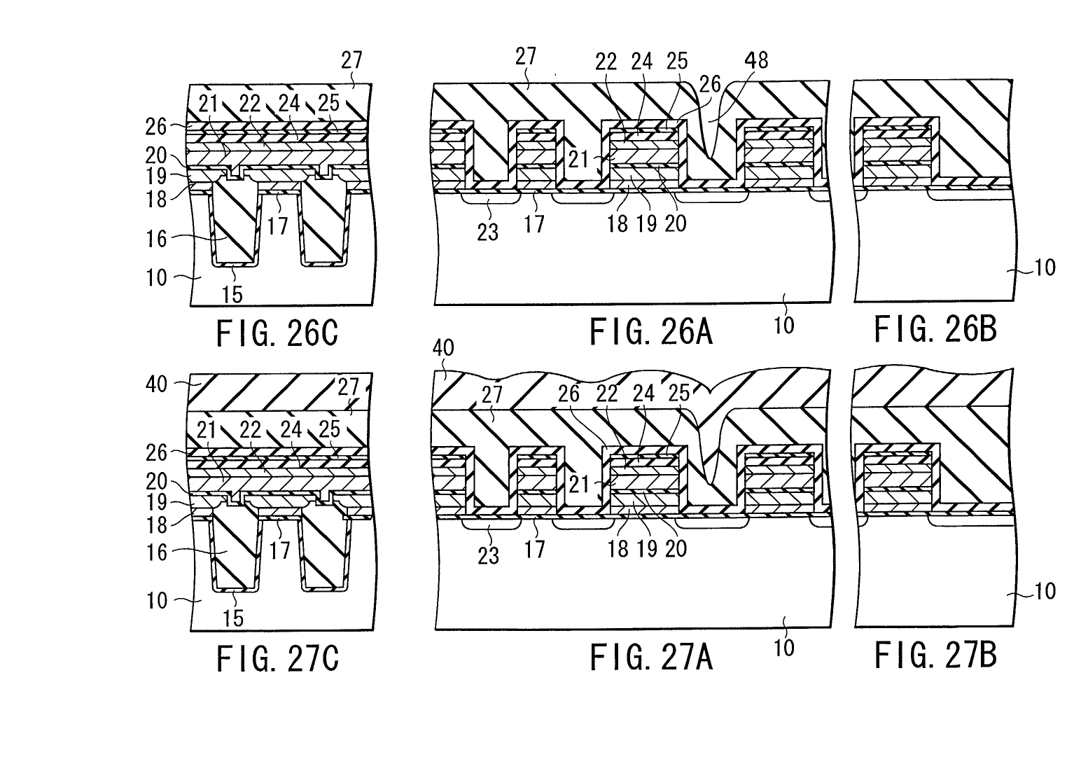

As shown in FIGS. 25A to 25C, a 300-nm thick interlevel insulating film 27 as a BPSG film having high step coverage is formed on the entire surface by normal pressure CVD. This BPSG film 27 is caused to reflow by performing annealing in a nitrogen ambient at 800° C. for 30 min, thus planarizing the surface (FIGS. 26A to 26C). However, if a step is present on the underlying layer on which the BPSG film is to be deposited and if this step is large, even the BPSG film having high step coverage is sometimes unable to well cover the step to form a pit 48.

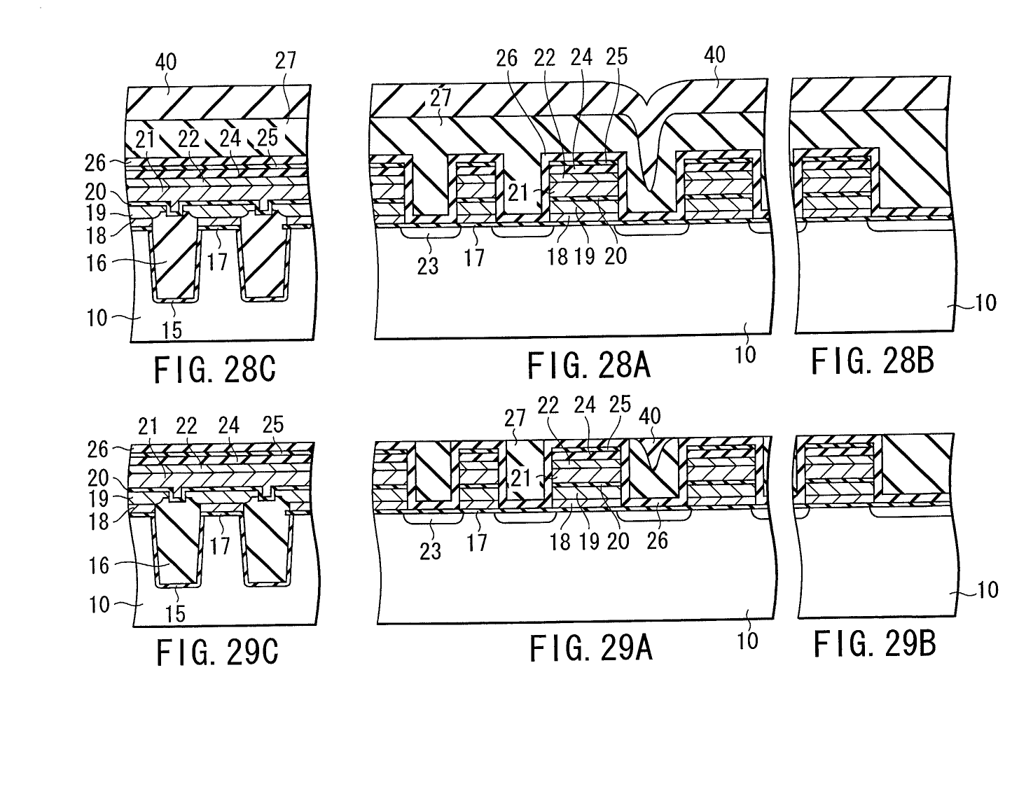

As shown in FIGS. 27A to 27C, therefore, a 300-nm thick BPSG film 40 is additionally deposited. This BPSG film 40 is allowed to reflow to fill the pit 48 formed in the BPSG film 27 (FIGS. 28A to 28C).

As shown in FIGS. 29A to 29C, these BPSG films 27 and 40 are polished by CMP using the silicon nitride film 26 as a stopper. After that, the surfaces of the BPSG films 27 and 40 are planarized by performing annealing in a nitrogen ambient at 800° C. for 15 min. Subsequently, the density of these BPSG films 27 and 40 is increased by performing annealing in a nitrogen ambient at 950° C. for 10 sec.

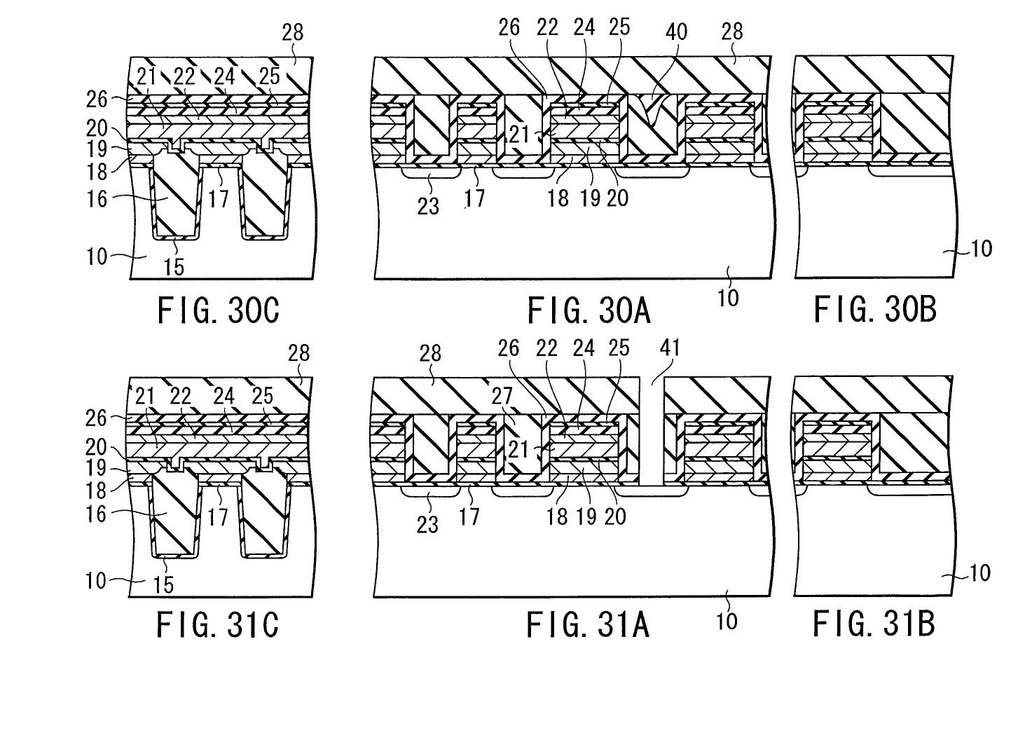

As shown in FIGS. 30A to 30C, a 350-nm thick silicon oxide film 28 is formed on the entire surface by plasma CVD. The surface of this silicon oxide film 28 is coated with a photoresist (not shown). This photoresist is patterned by photolithography into the formation pattern of a contact hole for contacting the impurity diffusion layer 23 of the select transistor.

RIE using the patterned photoresist as a mask is performed to first etch the silicon oxide film 28 and the BPSG films 27 and 40. After the photoresist is removed, RIE using the silicon oxide film 28 as a mask is performed to etch the silicon nitride film 26 and the gate insulating film 17, thereby forming a contact hole 41 (FIGS. 31A to 31C). After that, the reaction product deposited on the side walls of the contact hole 41 when RIE is performed is removed by O₂-plasma and a solution mixture of sulfuric acid and hydrogen peroxide.

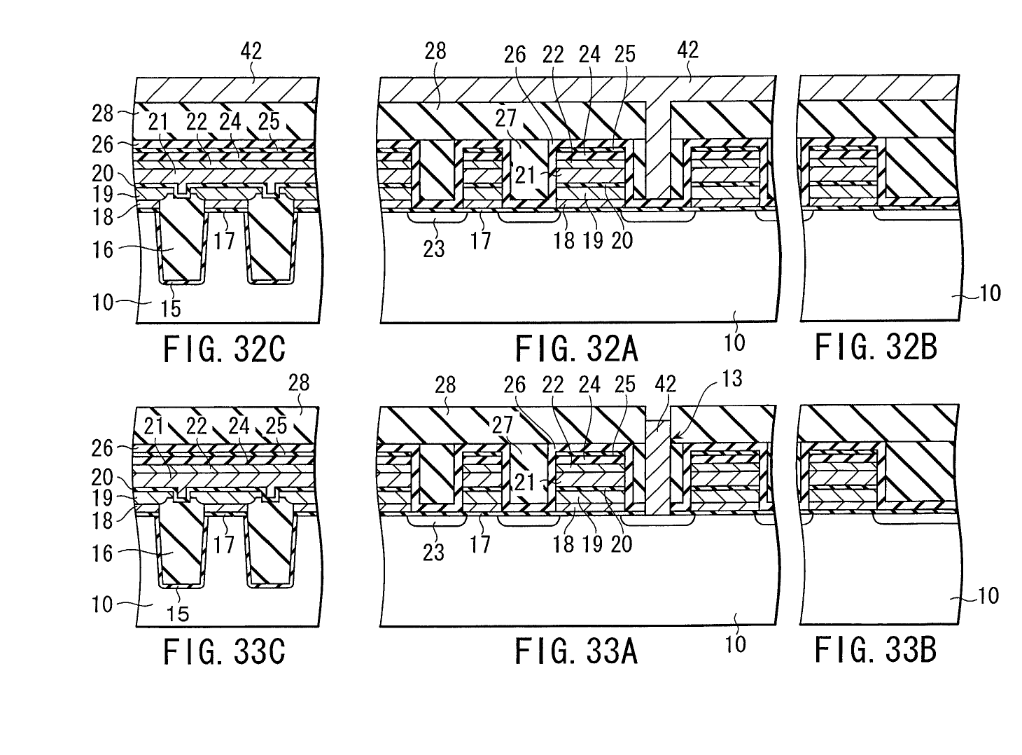

As shown in FIGS. 32A to 32C, a 300-nm thick polysilicon film 42 is formed on the entire surface by low pressure CVD to fill the contact hole 41.

After that, as shown in FIGS. 33A to 33C, the polysilicon film 42 is etched to a desired height in the contact hole 41 by CDE (Chemical Dye Etching). The residual polysilicon film 42 is annealed in a nitrogen ambient at 950° C. for 10 sec to form a contact plug 13.

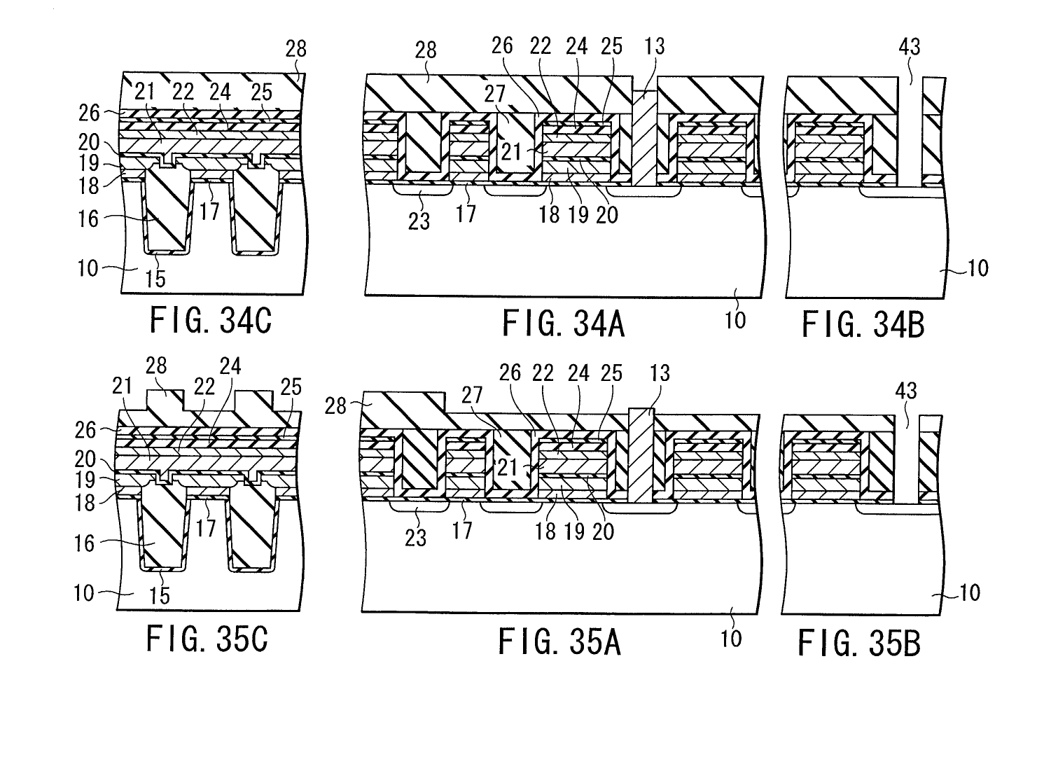

The surface of the silicon oxide film 28 is then coated with a photoresist (not shown). This photoresist is patterned into the formation pattern of a contact hole for contacting the impurity diffusion layer 23 of the transistor in a peripheral circuit. RIE using the patterned photoresist as a mask is performed to etch the silicon oxide film 28 and the BPSG film 27. After the photoresist is removed, RIE using the silicon oxide film 28 as a mask is performed to etch the silicon nitride film 26 and the gate insulating film 17, thereby forming a contact hole 43 as shown in FIGS. 34A to 34C. After that, the reaction product deposited on the side walls of the contact hole 43 when RIE is performed is removed by O₂-plasma and a solution mixture of sulfuric acid and hydrogen peroxide.

After that, the surface of the silicon oxide film 28 is coated with a photoresist (not shown). The silicon oxide film 28 is then patterned by lithography and etching into the wiring pattern of a bit line connecting to the impurity diffusion layer of the select transistor and into the wiring pattern of a line connecting to the impurity diffusion layer of the transistor in the peripheral circuit. The photoresist and the reaction product deposited by the etching are removed to obtain a structure shown in FIGS. 35A to 35C. In addition, an impurity is doped by ion implantation into the semiconductor substrate at the bottom of the contact hole 43. The doped impurity is activated by RTA (Rapid Thermal Annealing) performed in a nitrogen ambient at 950° C.

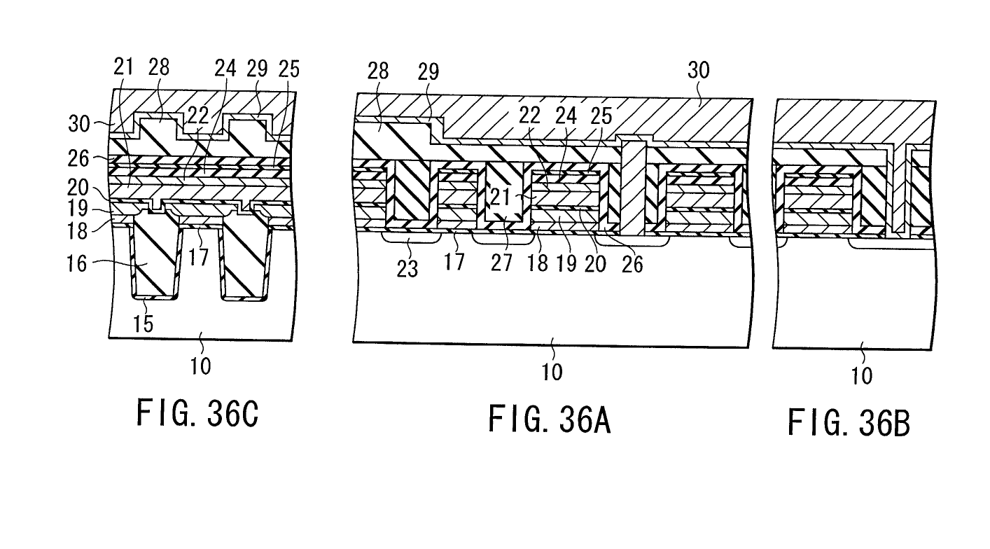

As shown in FIGS. 36A to 36C, a 300-nm thick titanium film 29 and a 400-nm tungsten film 30 are formed in this order on the entire surface by PVD.

As shown in FIGS. 37A to 37C, the titanium film 29 and the tungsten film 30 are planarized by CMP until the silicon oxide film 28 in a region where no bit line is to be formed. Annealing is then performed in a hydrogen-containing nitrogen ambient at 400° C. for 30 min.

After that, a BPSG film 31 as a second interlevel insulating film is deposited on the entire surface. A metal interconnecting layer is further formed, as needed, on this BPSG film 31. On the metal interconnecting layer and the BPSG film 31, a silicon nitride film is formed as a passivation film 32 by plasma CVD or the like. To improve the reliability of the metal interconnecting layer, a PSG (Phosphorous Silicate Glass) film formed by thermal CVD or a silicon oxide film formed by plasma CVD may also be interposed between the metal interconnecting layer and the passivation film 32. After that, a coating material 33 for protecting the semiconductor memory is formed on the entire surface, and holes are formed in a region where bonding pads are positioned, thereby completing the semiconductor memory as shown in FIGS. 7A to 7C.

In the nonvolatile semiconductor memory and its fabrication method as described above, the BPSG films 27 and 40 are formed as interlevel insulating films so as to cover a MOS transistor on the silicon substrate 10, and these BPSG films 27 and 40 are then polished until the silicon nitride film 26 on the control gates CG (select gates SG) is exposed. Since this can decrease the film thicknesses of the interlevel insulating films, the aspect ratios of the contact holes 41 and 43 can be reduced. Accordingly, these contact holes 41 and 43 can be well filled with conductive materials in the subsequent steps.

Also, the BPSG film 27 does not exist on the control gates CG (select gates SG), so the reflow of the BPSG film 27 caused by the shrinkage of the silicon oxide film 28 upon annealing can be minimized. Since this can suppress shape changes of the contact holes 41 and 43, it is possible to prevent contact failures and improve the reliability of the nonvolatile semiconductor memory.

Note that the steps of polishing the BPSG films 27 and 40 need not be terminated when the silicon nitride film 26 on the control gates CG (select gates SG) is exposed; the silicon nitride film 26 can be partly or entirely removed at once.

Furthermore, the above embodiment is explained by taking a NAND flash EEPROM as an example. However, the present invention is naturally applicable to a NOR flash EEPROM as well as to a NAND memory.

FIG. 38 is a sectional view, taken along the bit line direction, of a memory cell array region of a NOR flash EEPROM. As shown in FIG. 38, memory cell transistors are formed on a semiconductor substrate 10 so as to connect in series by sharing adjacent impurity diffusion layers 23. A BPSG film 27 is formed between adjacent gates of these memory cell transistors, and a silicon oxide film 28 is formed on this BPSG film 27 and a silicon nitride film 26. Contact plugs 13 are so formed to connect to the drain regions of the memory cell transistors. These contact plugs 13 are connected to a common bit line BL made of a titanium film 29 and a tungsten film 30. As described above, the BPSG film 27 covering the memory cell transistors is not formed on control gates CG, so the aspect ratio of contact holes can be reduced. Accordingly, effects similar to those explained in the above-mentioned NAND flash EEPROM can be obtained.

The present invention is, of course, applicable not only to a flash EEPROM but also to semiconductor memories such as a DRAM (Dynamic Random Access Memory) having trench or stacked capacitors and an EPROM having a two-layered gate structure. Furthermore, the present invention can be extensively applied not only to semiconductor memories but also to other semiconductor devices and their fabrication methods.

As has been described above, the present invention can provide a nonvolatile semiconductor memory and a method of fabricating the same, capable of preventing a shape change of a contact hole and improving the quality of burying by reducing the aspect ratio of the contact hole, thereby improving the reliability of interconnections.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a plurality of impurity diffusion regions selectively formed on said semiconductor substrate;
a plurality of insulated gate electrodes each formed on said semiconductor substrate between two adjacent ones of said plurality of impurity diffusion regions;
a first insulating film formed on said semiconductor substrate to bury said plurality of gate electrodes so as to expose an upper surface of each of said gate electrodes;
a second insulating film formed on said plurality of gate electrodes and on said first insulating film and not substantially containing boron and phosphorous; and
a conductive contact plug extending through said first and said second insulating film and connecting to a predetermined one of said plurality of impurity diffusion regions.

2. The device according to claim 1, where said first insulating film is a silicon oxide film containing boron and phosphorous, and said second insulating film is a silicon oxide film.

3. The device according to claim 1, further comprising a third insulating film formed between said plurality of gate electrodes and said first and said second insulating film, and between a major surface of said semiconductor substrate between said plurality of gate electrodes and said first insulating film.

4. The device according to claim 3, wherein said third insulating film is a member selected from the group consisting of a silicon oxide film and silicon nitride film.

5. The device according to claim 3, wherein an upper surface of said first insulating film is substantially flush with an upper surface of said third insulating film.

6. A nonvolatile semiconductor memory comprising:
a semiconductor substrate;
a first gate insulating film formed on said semiconductor substrate;
a first gate electrode formed on said first gate insulating film;
a second gate insulating film formed on said first gate electrode;
a second gate electrode formed on said second gate insulating film and at least partly overlapping said first gate electrode;
a first insulating film formed on said second gate electrode;
a second insulating film formed on at least side walls of a stacked gate structure and on said semiconductor substrate, said stacked gate structure being formed by stacking said first gate insulating film, said first gate electrode, said second gate insulating film, said second gate electrode, and said first insulating film;
a third insulating film formed on said semiconductor substrate so as to bury side wall portions of said stacked gate structure, and having an upper surface reaching said first insulating film;
a fourth insulating film formed on said first and third insulating films and not substantially containing boron and phosphorous; and
a conductive member buried in a contact hole reaching said semiconductor substrate through said second, said third, and said fourth insulating film.

7. The memory according to claim 6, wherein at least a partial region of an upper surface of said first insulating film reaches said fourth insulating film.

8. The memory according to claim 6, wherein said third insulating film is a silicon oxide film containing boron and phosphorous.

9. The memory according to claim 6, wherein said first insulating film is a member selected from the group consisting of a silicon oxide film and a silicon nitride film, said second insulating film is a silicon nitride film, and said fourth insulating film is a silicon oxide film.

10. The memory according to claim 6, wherein an upper surface of said third insulating film is flush with an upper surface of said first insulating film.

11. A semiconductor device fabrication method comprising the steps of:
forming a plurality of insulated gate electrodes on a semiconductor substrate;
forming a third insulating film on at least the plurality of gate electrodes;
forming a first insulating film on the third insulating film and on the semiconductor substrate so as to bury regions between the plurality of gate electrodes;
planarizing the first insulating film by removal until the third insulating film on the gate electrodes is exposed;
forming a second insulating film not substantially containing boron and phosphorous after the step of planarizing the first insulating film;
forming a contact hole reaching the semiconductor substrate through the first and the second insulating film; and
burying a conductive member reaching the semiconductor substrate into the contact hole.

12. The method according to claim 11, wherein the step of forming the third insulating film comprises the step of forming a silicon nitride film.

13. The method according to claim 11, wherein the step of forming the first insulating film comprises the step of forming a silicon oxide film containing boron and phosphorous.

14. The method according to claim 11, wherein the step of forming the second insulating film comprises the step of forming a silicon oxide film not substantially containing boron and phosphorous.

15. A nonvolatile semiconductor memory fabrication method comprising the steps of:
forming a first gate insulating film on a semiconductor substrate;
forming a first gate electrode on the first gate insulating film;
forming a second gate insulating film on the first gate electrode;
forming, on the second gate insulating film, a second gate electrode at least partly overlapping the first gate electrode;
forming a first insulating film on the second gate electrode;
forming a second insulating film on a stacked gate structure and on the semiconductor substrate, the stacked gate structure being formed by stacking the first gate insulating film, the first gate electrode, the second gate insulating film, the second gate electrode, and the first insulating film;
forming a third insulating film on the semiconductor substrate so as to bury the stacked gate structure;
planarizing the third insulating film by reflow;
removing the surface of the third insulating film until the second insulating film on the upper surface of the stacked gate structure is reached;
forming a fourth insulating film on the second and the third insulating film;
forming a contact hole reaching the semiconductor substrate through the second, the third, and the fourth insulating film; and
burying a conductive member reaching the semiconductor substrate into the contact hole.

16. The method according to claim 15, further comprising, after the step of removing the surface of the third insulating film until the second insulating film on an upper surface of the stacked gate structure is reached, the step of;
removing the second and the third insulating film to expose at least a partial region of the first insulating film on the stacked gate structure.

17. The method according to claim 15, wherein the step of forming the first insulating film comprises the step of forming a film selected from the group consisting of a silicon oxide film and a silicon nitride film.

18. The method according to claim 15, wherein the step of forming the second insulating film comprises the step of forming a silicon nitride film.

19. The method according to claim 15, wherein the step of forming the third insulating film comprises the step of forming a silicon oxide film containing boron and phosphorous.

20. The method according to claim 15, wherein the step of forming the fourth insulating film comprises the step of forming a silicon oxide film.
